(19) United States
(12) Patent Application Publication
(10) Pub. No.: US 2007/0047329 A1
(43) Pub. Date: Mar. 1, 2007

(54) Configurable flash memory

(76) Inventors: Mikolaj Kolakowski, Reda (PL); Jacek Wysoczynski, Banino (PL); Adam Marek, Gdansk (PL)

Correspondence Address: TROP PRUNER & HU, PC, 1616 S. VOSS ROAD, SUITE 750, HOUSTON, TX, 77057-2631, US

(21) Appl. No.: 11/214,073

(22) Filed: Aug. 29, 2005

(51) Int. Cl. G11C 16/04

(52) U.S. Cl. 365/185.33

(57) ABSTRACT

A flash memory may be reconfigurable so that the memory space arrangement of the flash array may be changed for particular applications. In one embodiment, a command or comment may be received by the flash memory. In response to the command, the flash memory may be reconfigured so that the arrangement of sectors or the organization of the memory within the flash array may be adapted to a specific application. Then, data may be written to the flash array so organized. In some embodiments, the flash array may, thereafter, be reconfigured for still other applications.

### BACKGROUND

This invention relates generally to flash memory.

Flash memory may be used for a variety of applications. Depending on the application, it may be desirable to use memory specifically configured for a particular application. Then, different memories may be used for different applications.

Generally, flash memories are arranged in sectors of given sizes. Certain sectors may be provided in particular sizes for storing particular code, such as a kernel, an operating system, or a boot loader, as examples.

One example is a flash memory that is adapted for a RedBoot (Red Hat's Embedded Debug and Bootstrap Program) boot loader. Such a boot loader has a number of components which must be fit within sectors arranged to match the sizes needed for those components. For example, there may be three eight-kilobyte regions reserved for the RedBoot boot loader and another three eight-kilobyte region for a copy of the RedBoot boot loader. Then, space is needed for a kernel, other operating system components, and a directory.

A standard flash memory may not be organized in the fashion used for a RedBoot loader. Thus, a dedicated flash memory is used that has a memory space organized appropriately for the RedBoot boot loader.

Certainly, there are other examples in which flash memory, as conventionally obtained, may not have the ideal memory space organization, resulting in specially adapted flash memories for particular applications.

### BRIEF DESCRIPTION OF THE DRAWINGS

FIG. 1 is a schematic depiction of one embodiment of the present invention;

FIG. 2 is an example of a memory space arrangement for a flash memory in accordance with one embodiment of the present invention;

FIG. 3 is a flow chart for configuring a flash memory in accordance with one embodiment of the present invention;

FIG. 4 is a flow chart for writing to an appropriately configured flash memory in accordance with one embodiment of the present invention;

FIG. 5 is a depiction of a flash memory in accordance with one embodiment of the present invention; and

FIG. 6 is a depiction of a system in accordance with one embodiment of the present invention.

### DETAILED DESCRIPTION

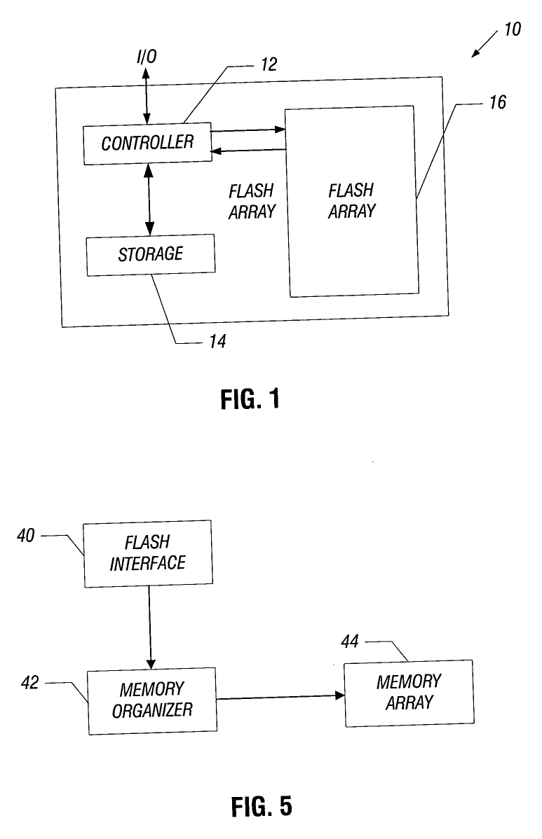

Referring to FIG. 1, a flash memory 10 may include a controller 12. The controller 12, in one embodiment, may be an embedded controller. However, any processor-based device may be utilized, including a microcontroller or a microprocessor. In some embodiments, other elements, including software elements, may implement the controller function.

The controller 12 receives inputs and outputs as indicated by the label “I/O” in FIG. 1. The controller 12 provides commands to the flash array 16. The flash array 16 includes the actual flash memory cells which store the data. Thus, the controller 12 can write to and read from the flash array 16.

The controller 12 may also have its own separate storage 14. The storage 14 may be implemented as a part of the flash array 16 in one embodiment. In other embodiments, the storage 14 may be separate from the flash array 16 and, in still other embodiments, the storage 14 may be incorporated within the controller 12. In some cases, the memory used for the storage 14 may not be a flash memory, but, instead, may be another type of memory such as a dynamic random access memory, a static random access memory, or other randomly accessible memory.

To implement a write to the flash array 16, conventionally, the controller 12 receives a command or a comment which places the controller 12 in a write mode. Once the controller 12 has received that command, which may be defined by a unique code, and the controller 12 has transitioned to the write mode, ensuing received data may be written by the controller 12 to the flash array 16. Thereafter, a command or comment may terminate the write mode.

Similarly, in order to read, in some embodiments, the controller 12 may receive an appropriate command or comment to transition the controller 12 to a read mode. Thereafter, read commands can be forwarded by the controller 12 to the flash array 16 to read the requested data.

Other commands or comments may also be received by the controller 12 in the form of input/output signals. For example, a comment may be used to lock certain sectors of the flash array 16.

Conventionally, many flash memories follow a so-called common flash memory interface (CFI) specification which is published by various flash memory manufacturers. Pursuant to this specification, any given flash memory is addressable by certain pre-defined comments. These comments may be provided as commands to a controller 12 which may be placed into an appropriate mode in response to receipt comments that correspond to a certain format.

Then, the controller 12 may implement the comment by locking a memory array, reading from the flash array, or writing to the flash array. For example, “A Common Flash interface (CFI) and Command Sets” is available from Intel corporation, application note 646, dated April 2000.

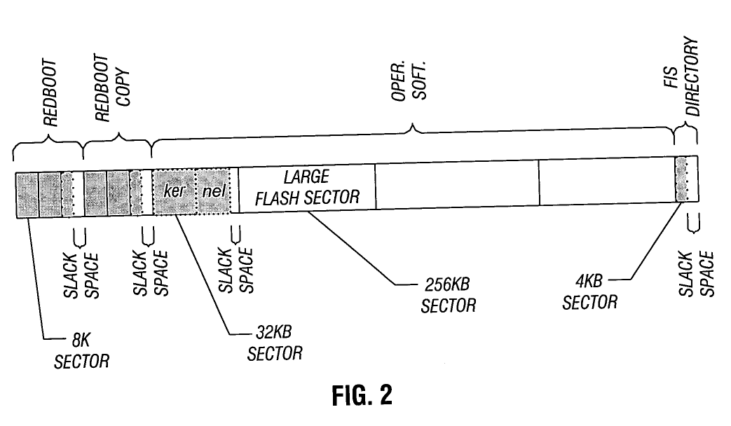

Referring to FIG. 2, the flash array 16, in accordance with one embodiment, may be configured to store a RedBoot boot loader. For example, the RedBoot boot loader may be loaded into three, eight byte sectors, as as indicated, including some slack space as also indicated. A RedBoot boot loader copy may also be loaded adjacent thereto. A kernel may be provided in 32 kilobyte sectors, as indicated, with slack space, as also indicated in FIG. 2. Then, a large flash sector of 256 kilobytes may be provided within an area that is reserved for the operating system. Finally, a flash image system (FIS) directory may include four kilobytes, together with slack space.

However, some flash memories may not be configured in a fashion suitable for RedBoot boot loaders. Conventionally, special memories must be obtained which are reconfigured for RedBoot boot loaders.

In some embodiments of the present invention, it is desirable to provide a flash memory which may be reconfigured for various applications such as storing a RedBoot loader, as indicated in FIG. 2. Other applications are also amenable to reconfiguration. Then, a standard flash memory may be reconfigured for special applications. The reconfigurability reduces the number of flash memory models that need to be offered, reducing costs.

In some embodiments of the present invention, the configuration or reconfiguration may be implemented through comments according to the common flash interface. The common flash interface specifies comments or commands used in all flash memories to appropriately operate those flash memories. For example, comments or commands may implement a write or read sequence or a locking of sectors in any commercially distributed flash memory that complies with the common flash interface.

In accordance with some embodiments of the present invention, an additional comment or command may be provided which enables the controller 12 to reconfigure the flash array sector arrangement or memory space arrangement in accordance with some specification provided by the command. In other embodiments, a command may select one of at least two prerecorded configurations.

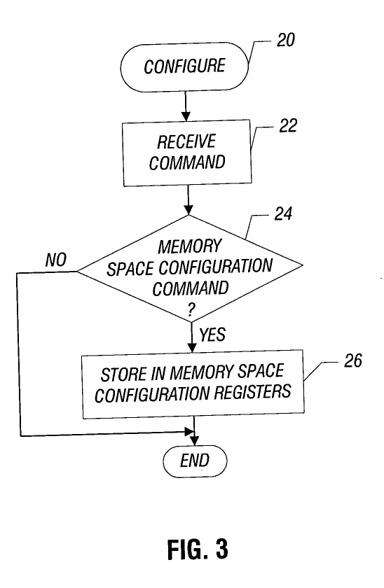

Referring to FIG. 3, a process 20 for configuring the flash array 16 may be implemented in software, hardware, or firmware. Initially, a command or comment is received as indicated in block 22. This command may be in a format compatible with the common flash interface and may be referred to as a command or a comment. Thus, the command may be code to configure the flash memory for receipt of a memory space configuration command. Once that command is received, as indicated in block 22, a check at diamond 24 identifies the comment or command and determines that the particular comment or command is a memory space configuration command.

In such case, the memory space may be configured in accordance with that command, as indicated in block 26. For example, the command may specify the arrangement of sectors set forth in FIG. 2, as one example. Then, the flash array 16 may be appropriately configured for a RedBoot boot loader or for some other application. Conversely, the array 16 may be configured conventionally for a conventional operating system and a conventional operating boot system loader. Other arrangements will occur to those of ordinary skill in the art.

The configuration data may accompany the command in one embodiment. The configuration data may be stored in a configuration register for either immediate or subsequent execution.

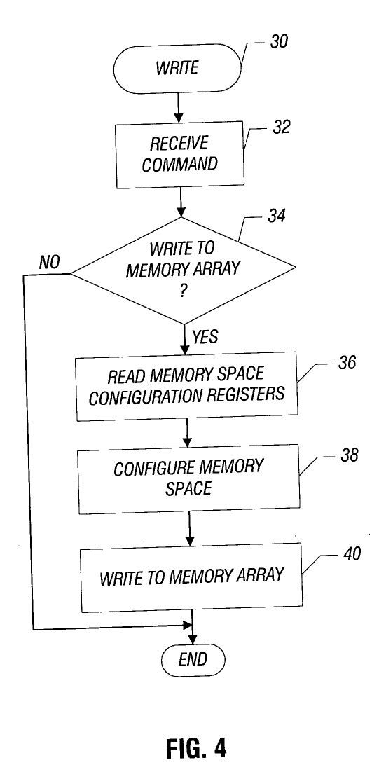

Referring to FIG. 4, after the memory space has been configured pursuant to the process 20, shown in FIG. 3, a write process 30 may be implemented. The write process 30 may be implemented in software, hardware, or firmware. In the case of a software implementation, the configure process 20 and the write process 30 may be implemented by machine accessible instructions stored either on the controller 22, in the storage 14, or in the flash array 16, to provide a few examples. Of course, such code may also be stored in some other memory not depicted.

A write command of an appropriate format may be received as indicated in block 32. In some embodiments, the write command may be a command or comment compliant with the common flash interface specification. Once the command is recognized as a write to a memory array, as determined in diamond 34, a memory space configuration register, set by the process 20, may be read as indicated in block 36. The memory space may then be configured, as indicated in block 38, and a write may occur to the memory array 40 in one embodiment.

In another embodiment, the configuration of the memory space may occur before the write command 30 is received. Thus, the configuration of the memory space, only after receiving a write command and in accordance with a previously received command to store a memory space configuration, is merely one embodiment of the present invention.

Referring to FIG. 5, in accordance with one embodiment of the present invention, the flash memory 10 may be implemented by a series of modules which may be software, hardware, or firmware. One module may be a flash interface 40. The flash interface 40 may receive inputs and outputs from external sources to read, write, configure, or perform other operations. The flash interface 40 may also receive instructions, such as comments or commands, in accordance with the common flash interface modified to include a command or comment for configuration of the flash array 16.

A memory organizer 42 receives information from the flash interface 40. The memory organizer 42 may then appropriately store a configuration setting or immediately configure the flash array 16 in accordance with a command or a comment that has been received. Then, the memory array 44 may be configured by that memory organizer 42, either logically or physically.

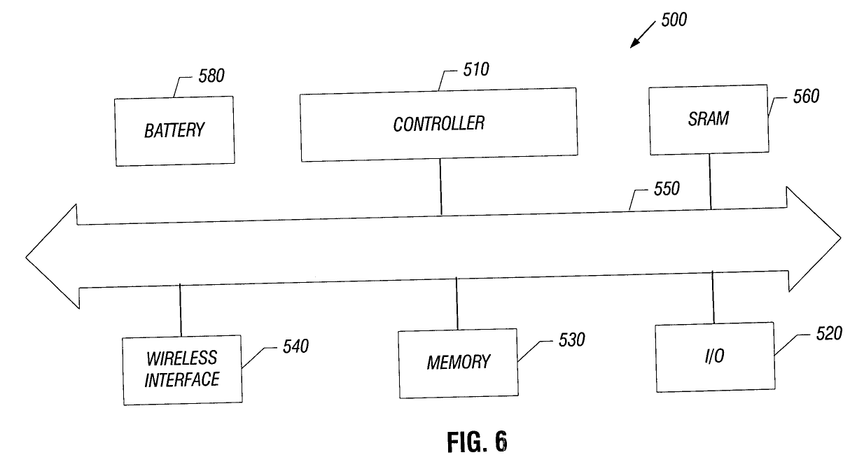

Turning to FIG. 6, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 10, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a configurable memory such as a memory 10 discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. a method comprising:
enabling a flash memory to have a reconfigurable memory space.

2. The method of claim 1 including adapting said memory to configure said space in response to a comment received by said memory.

3. The method of claim 1 including adapting said memory to, in response to detection of a unique code, store memory configuration data.

4. The memory of claim 3, including enabling said memory to configure said memory according to said data in response to receipt of a write command.

5. The method of claim 1 including detecting a code indicating a write command and writing to said memory according to stored configuration data.

6. The method of claim 1 including enabling said memory to reconfigure its memory space repeatedly.

7. The method of claim 6 including enabling said memory to implement an externally supplied memory space configuration command.

8. The method of claim 1 including enabling said flash memory to, in response to a command, change the sector arrangement of said memory.

9. The method of claim 1 including enabling a controller to execute a memory space configuration command.

10. The method of claim 9 including enabling said controller to store said memory space configuration commands on said memory.

11. A flash memory comprising:
a memory array;
a flash interface to receive input commands;
a memory organizer coupled to said interface and said array to configure said array according to a command received by said interface.

12. The memory of claim 11 wherein said organizer to repeatedly reconfigure said array.

13. The memory of claim 11 wherein said organizer includes a controller.

14. The memory of claim 13 wherein said organizer includes a storage coupled to said controller, said storage to store array configuration data.

15. The memory of claim 11, said organizer to change the arrangement of sectors in said array.

16. The memory of claim 11 to enter a configuration mode in response to the detection of a unique code.

17. The memory of claim 16, said memory to enter a write mode in response to the detection of a unique code.

18. The memory of claim 17, said memory to execute, in a write mode, a memory configuration established in said configuration mode.

19. A computer accessible medium storing instructions that, if executed, enable a processor-based system:
reconfigure a memory space organization of a flash array.

20. The medium of claim 19 further storing instructions to configure said memory space organization in response to a comment received by a memory including said flash array.

21. The medium of claim 19 further storing instructions to, in response to detection of a unique code, store memory configuration data.

22. The medium of claim 21 further storing instructions to configure said flash array according to said data in response to receipt of a write command.

23. The medium of claim 19 further storing instructions to detect a code indicating a write command and write to said flash array according to a stored configuration data.

24. The medium of claim 19 further storing instructions to reconfigure the flash array repeatedly.

25. The medium of claim 19 further storing instructions to enable said memory to, in response to a command, change the sector arrangement of said array.

26. The medium of claim 19 further storing instructions to store memory space configuration commands on said array.

27. A system comprising:
a processor;
a static random access memory coupled to said processor; and
a flash memory including a memory array, a flash interface to receive input commands and a memory organizer coupled to said interface and said array to configure said array according to a command received by said interface.

28. The system of claim 27 wherein said organizer includes a controller.

29. The system of claim 28 wherein said organizer includes a storage coupled to said controller, said storage to store array configuration data.

30. The system of claim 28, said organizer to change the arrangement of sectors in said memory.
